(19) United States
(12) Patent Application Publication
(10) Pub. No.: US 2004/0232566 A1
(43) Pub. Date: Nov. 25, 2004

(54) Semiconductor device and method of manufacturing the same

(76) Inventor: Kiyoshi Mita, Gunma (JP)

Correspondence Address: FISH & RICHARDSON P.C., CITIGROUP CENTER 52ND FLOOR, NEW YORK, NY, 10022-4611, US

(21) Appl. No.: 10/813,782

(22) Filed: Mar. 31, 2004

(30) Foreign Application Priority Data
May 7, 2003 (JP) P. 2003-129094

(51) Int. Cl. H01L 23/495; H01L 23/28

(52) U.S. Cl. 257/787

(57) ABSTRACT

To provide a semiconductor device with increased reliability between a mounting substrate and sealing resin and a method of manufacturing the same. The semiconductor device includes a mounting substrate including a step portion in the periphery; first and second conductive patterns formed on the front and back surfaces of the mounting substrate, respectively; a semiconductor element fixed to the mounting substrate and electrically connected to the first conductive patterns; and sealing resin covering the front surface of the mounting substrate and the step portion and seals the semiconductor element.

### BACKGROUND OF THE INVENTION

The present invention relates to a semiconductor device, and specifically, relates to a semiconductor device in which a plated film is attached to bonding pads formed on the surface of a mounting substrate and a method of manufacturing the same.

A description will be given of a structure of a semiconductor device 100 of conventional type with reference to FIG. 7.

First pads 105 are formed on the front surface of a mounting substrate 104 composed of a flexible sheet or a glass epoxy substrate, and second pads 106 electrically connected to the first pads 105 are formed on the back surface thereof. The first and second pads 105 and 106 are electrically connected to each other through holes penetrating the mounting substrate 104.

A semiconductor element 101 is fixed on the mounting substrate 104 and electrically connected to the first pads 105 through fine metallic wires 102. The semiconductor element 101 and the surface of the mounting substrate 104 are sealed with a sealing resin 103.

However, in the aforementioned semiconductor device 100, the sealing resin 103 which seals the semiconductor element 101 covers only the front surface of the mounting substrate 104. Furthermore, adhesion between the mounting substrate 104 composed of glass epoxy resin and the sealing resin 103 is low. Accordingly, there is a problem in adhesion between the mounting substrate 104 and the sealing resin 103.

Furthermore, electroplating of the first pads 105 or the second pads 106 requires plating lines which connect the pads 105 or 106 to each other. In such a case, there is a problem that the plating lines are exposed to the outside from the interface of the sealing resin 103 and the mounting substrate 104 to reduce the reliability of the semiconductor device. Moreover, in the case of manufacturing a plurality of semiconductor devices by a manufacturing method of an MAP (Multi Area Package) or the like, plating lines are separated in a dicing step which separates semiconductor devices. Therefore, there is a problem that water filtrates into the semiconductor device along the plating lines exposed to the outside.

### SUMMARY OF THE INVENTION

The embodiment of present invention was made in the light of the aforementioned problems, and a main object of the embodiment of present invention is to provide a semiconductor device with increased reliability between a mounting substrate and sealing resin and provide a method of manufacturing the same.

A semiconductor device according to the embodiment of present invention includes: a mounting substrate having a step portion in the periphery; a conductive pattern formed on a surface of the mounting substrate; a semiconductor element fixed to the mounting substrate and electrically connected to the conductive pattern; and sealing resin covering the surface of the mounting substrate and the step portion and sealing the semiconductor element.

A method of manufacturing a semiconductor device according to the embodiment of present invention includes the steps of: forming first conductive patterns which constitute units and common plating lines on a front surface of a substrate, each of the units including bonding pads and plating lines extending from the respective bonding pads to the periphery, the common plating lines electrically connecting the plating lines of the units; forming second conductive patterns on a back surface of the substrate, the second conductive patterns being electrically connected to the respective first conductive patterns; forming a plated film to the surface of the first conductive patterns by electroplating using the common plating lines; forming grooves on the front surface of the substrate by dicing the front surface of the substrate including the common plating lines to electrically separate the conducive patterns; placing semiconductor elements on the front surface of the substrate; providing sealing resin which fills the grooves and seals the semiconductor elements; and separating the semiconductor elements by dicing the substrate and the sealing resin at borders of the units.

### BRIEF DESCRIPTION OF THE DRAWINGS

FIGS. 1A and 1B are a plan view and a cross-sectional view showing a semiconductor device according to the embodiment of present invention, respectively.

FIGS. 2A to 2C are a plan view, an enlarged plan view, and a cross-sectional view showing a method of manufacturing the semiconductor device according to the embodiment of present invention.

FIGS. 3A and 3B are a plan view and a cross-sectional view showing the method of manufacturing the semiconductor device according to the embodiment of present invention.

FIG. 4 is a cross-sectional view showing the method of manufacturing the semiconductor device according to the embodiment of present invention.

FIG. 5 is a cross-sectional view showing the method of manufacturing the semiconductor device according to the embodiment of present invention.

FIG. 6 is a cross-sectional view showing the method of manufacturing the semiconductor device according to the embodiment of present invention.

FIG. 7 is a cross-sectional view illustrating a conventional semiconductor device.

### DETAILED DESCRIPTION OF PREFERRED EMBODIMENT

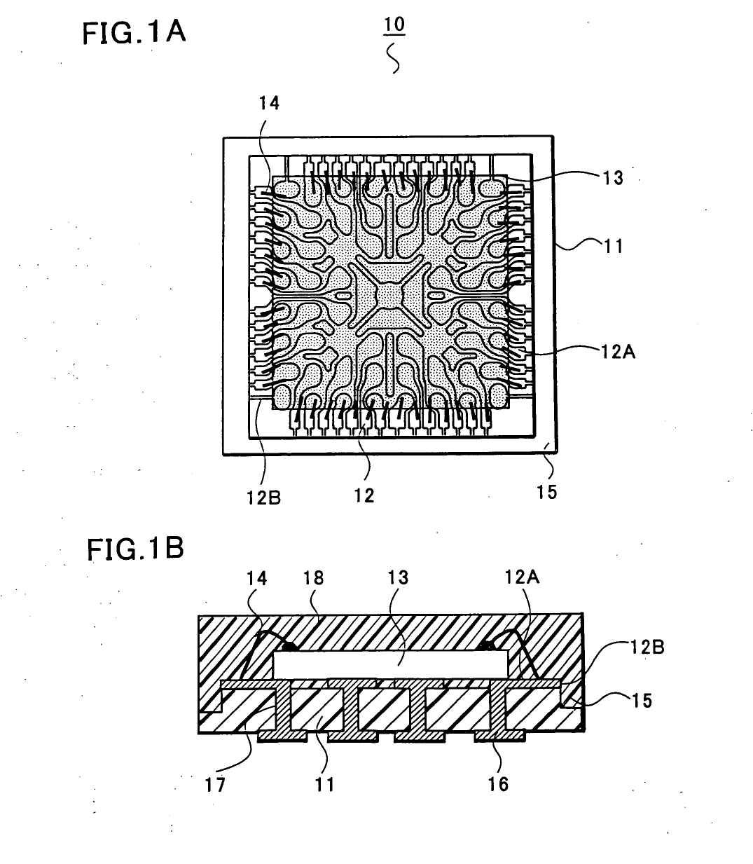

First, a description will be given of a structure of a semiconductor device 10 according to the present embodiment with reference to FIGS. 1A and 1B. FIG. 1A is a plan view of the semiconductor device 10, and FIG. 1B is a cross-sectional view thereof.

The semiconductor device 10 of the present embodiment includes a mounting substrate 11, first and second conductive patterns 12 and 16, a semiconductor element 13, and sealing resin 18. The mounting substrate 11 includes a step portion 15 in the periphery thereof. The first and second conductive patterns 12 and 16 are formed in the front and back surfaces of the mounting substrate 11, respectively. The semiconductor element 13 is fixed to the mounting substrate 11 and electrically connected to the first conductive patterns 12. The sealing resin 18 covers the front surface and the step portion 15 of the mounting substrate 11 and seals the semiconductor element 13. The semiconductor device 10 with such a structure will be described in detail below.

The mounting substrate 11 is an interposer of the semiconductor device 10 and composed of glass epoxy material or the like. The conductive patterns are formed on both surfaces of the mounting substrate 11, and the semiconductor element 13 is mounted on the front surface thereof. In the periphery of the mounting substrate 11, the step portion 15 is provided. The depth of this step portion 15 can be, for example, about half the thickness of the mounting substrate 11. By providing the step portion 15, it is possible to prevent plating lines 12B from being exposed to the outside. Furthermore, the sealing resin 18 also fills the step portion 15. Therefore, the adhesion between the mounting substrate 11 and the sealing resin 18 is increased especially because the side surface of the step portion 15 adheres to the sealing resin 18.

Referring to FIG. 1A, the first conductive patterns 12 are formed on the front surface of the mounting substrate 11 by etching metal such as copper. Herein, part of the first conductive patterns 12 forms the bonding pads 12A so as to surround the semiconductor element 13. Furthermore, the plating lines 12B are formed extending from the respective bonding pads 12A to the step portion 15. The plating lines 12B are used for conducting electric current to the conductive patterns when the plated film is formed by electroplating. Moreover, wiring portions extending inward from the individual bonding pads 12A are provided and electrically connected through connection portions 17 to the second conductive patterns 16 which forms electrodes in a matrix. On the surface of the first conductive patterns 12, a plated film of nickel or gold is formed.

The second conductive patterns 16 are formed on the back surface of the mounting substrate 11 and form the electrodes in a matrix. Moreover, it is possible to form a land grid array (LGA) with the second conductive patterns 16, or form a ball grid array (BGA) by applying a soldering material such as solder to each electrode. The second conductive patterns 16 are electrically connected to the first conductive patterns 12 through the connection portions 17 penetrating the mounting substrate 11. The aforementioned plated film is also attached to the second conductive patterns 16.

The semiconductor element 13 is, for example, an IC chip and fixed to the mounting substrate 11 with an insulating adhesive interposed therebetween. Use of such an insulating adhesive allows the first conductive patterns 12 to be laid under the semiconductor element 13. The semiconductor element 13 and the first conductive patterns 12 are electrically connected to each other through the fine metallic wires 14.

The sealing resin 18 is composed of, for example, thermosetting resin and covers the semiconductor element 13. The sealing resin 18 also fills the step portion 15, so that the adhesion between the mounting substrate 11 and the sealing resin 18 is improved. Moreover, the surface of the step portion 15 is rough because the step portion 15 is formed by dicing. Accordingly, the adhesive strength therebetween can be further increased.

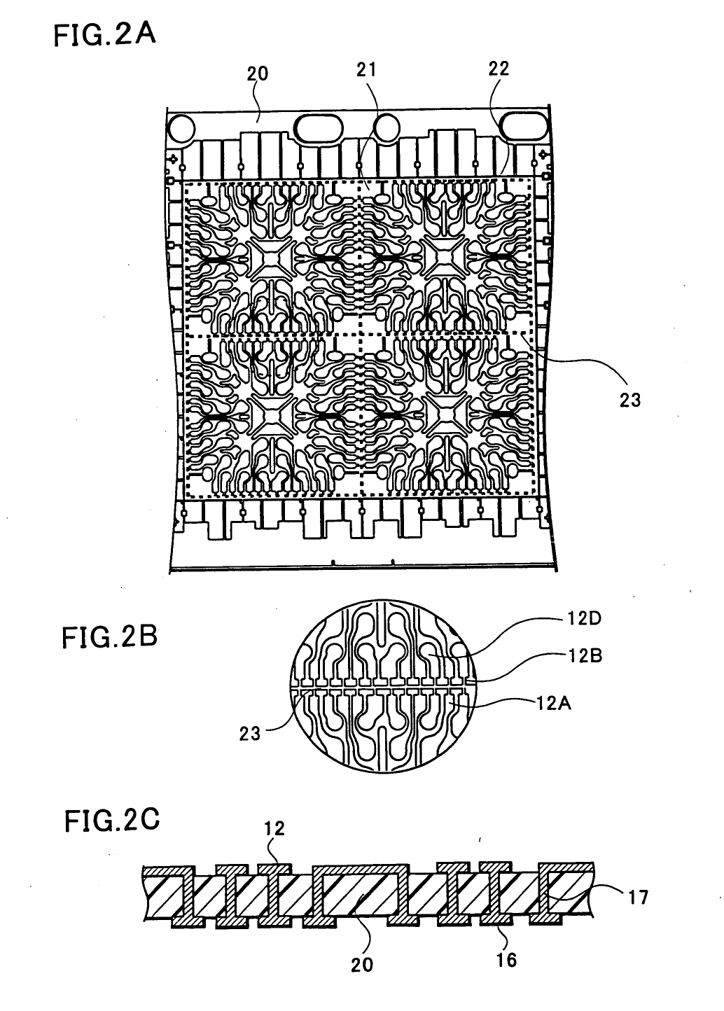

Next, the method of manufacturing the semiconductor device according to the present embodiment will be described referring to FIGS. 2A and 2B to FIG. 6. The method of manufacturing the semiconductor device according to the present embodiment includes: a step of forming the first conductive patterns 12 constituting units 21 and common plating lines 23 on the front surface of a substrate 20, each of the units 21 being composed of the bonding pads 12A and the plating lines 12B extending from the bonding pads 12A to the periphery, the common plating lines, 23 electrically connecting the plating lines 12B of the units 21; a step of forming the second conductive patterns 16 on the back surface of the substrate 20, the second conductive patterns 16 being electrically connected to the first conductive patterns 12; a step of attaching a plated film to the surface of the first conductive patterns 12 by electroplating using the common plating lines 23; a step of forming grooves 24 on the front surface of the substrate 20 by dicing the front surface of the substrate 20 including the common plating lines 23 to electrically separate the individual conductive patterns; a step of placing the semiconductor elements 13 on the front surface of the substrate 20; a step of providing the sealing resin 18 such that the sealing resin 18 fills the grooves 24 and seals the semiconductor elements 13; and a step of separating individual semiconductor devices by dicing the substrate 20 and the sealing resin 18 at borders of the units 21.

Referring to FIGS. 2A to 2C, first, the substrate 20 with the conductive patterns formed is prepared. FIGS. 2A to 2C are a plan view of a block 22 including the plurality of units 21 formed thereon, an enlarged plan view of FIG. 2A, and a cross-sectional view, respectively.

The substrate 20 is made of resin such as glass epoxy material, and the first conductive patterns 12 are formed on the front surface thereof. The second conductive patterns 16 electrically connected to the first conductive patterns 12 through the connection portions 17 are formed on the back surface of the substrate 20.

Referring to FIGS. 2A and 2B, on the substrate 20, one block 22 is formed by arranging the plurality of units 21 in a matrix, and each unit 21 includes conductive patterns constituting one semiconductor device. The structure of the first conductive patterns 12 formed in each unit 21 will be described. The bonding pads 12A are formed of part of the first conductive patterns 12 so as to surround the semiconductor element 13 to be placed. From the individual bonding pads 12A, the plating lines 12B are extended to the periphery of the unit 21 and connected to the common plating lines 23. To implement the BGA or LGA structure, wiring portions 12D are extended from the respective bonding pads 12A toward the center.

In other words, the bonding pads 12A of each unit 21 are connected to the common plating lines 23 through the respective plating lines 12B. The common plating lines 23 are extended along border lines of the units 21 into a grid. The common plating lines 23 are also extended so as to surround each unit 21. Accordingly, the bonding pads 12A are electrically connected to each other by the plating lines 12B and the common plating lines 23. Herein, one block 22 is composed of four units 21, but may be composed of any number of units 21. Moreover, a plurality of the blocks 22 may be arranged in the substrate 20.

Referring to FIG. 2C, the second conductive patterns 16 forming the electrodes on the back surface are electrically connected through the connection portions 17 to the first conductive patterns 12 which form the bonding pads 12A and the like. Accordingly, the second conductive patterns 16 are also electrically conducted to the common plating lines 23 by electrically connecting the first conductive patterns 12 by the plating lines as described above.

Subsequently, the surfaces of the first and second conductive patterns 12 and 16 are coated with a plated film by electroplating. The first and second conductive patterns 12 and 16 are electrically connected to each other by the common plating lines 23 as described above. Accordingly, the electroplating can be performed by providing an electrode for plating in any pattern of the first and second conductive patterns 12 and 16. Herein, the plated film to be formed is, for example, a plated nickel or gold film. These plated films have very high reliability because these films are formed by electroplating.

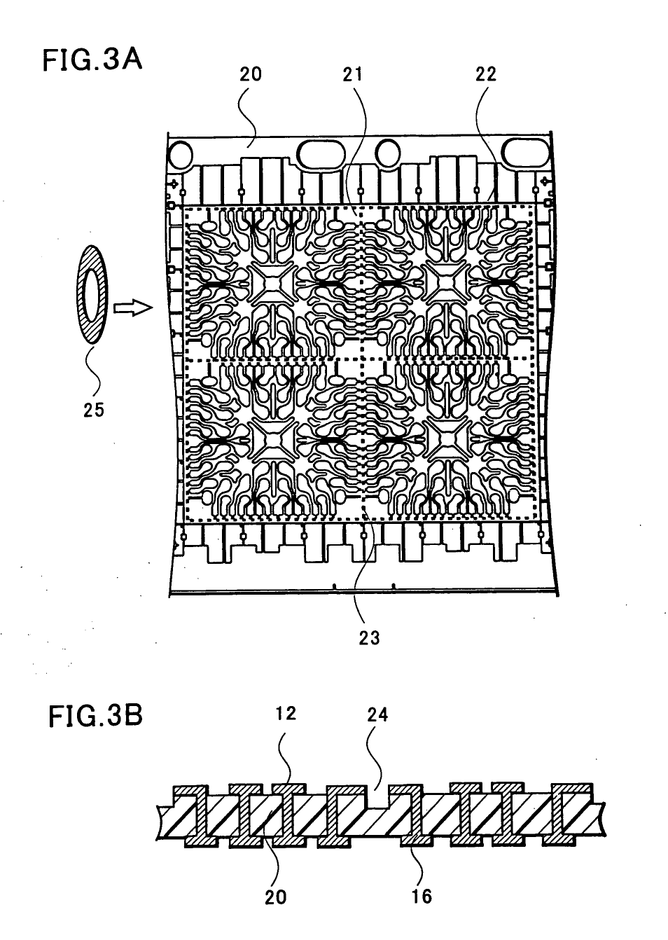

Referring to FIG. 3, the surface of the substrate 20 is diced using a dicing saw 25 including the common plating lines 23. Specifically, the surface of the substrate 20 is diced along the borders of the units 21 to remove the common plating lines 23. The individual bonding pads formed of part of the first conductive patterns are thus electrically separated from each other. Moreover, the grooves 24 are formed in the periphery of each unit 21. To ensure the removal of the common plating lines 23, the dicing saw 25 may have a width larger than the width of the common plating lines 23.

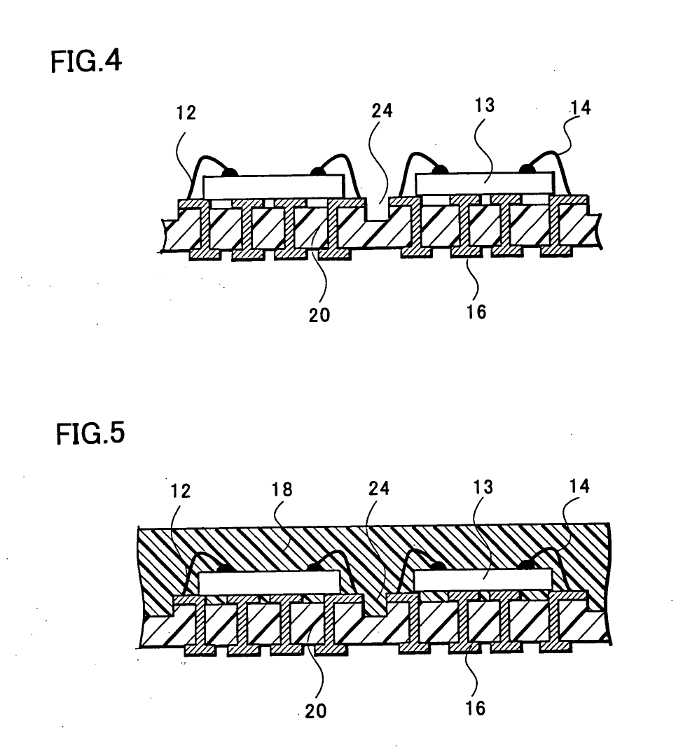

Referring to FIG. 4, each semiconductor element 13 is fixed to each unit 21. The fixing may be performed with an insulating adhesive. Subsequently, the first conductive patterns 12 and the semiconductor element 13 are electrically connected using the fine metallic wires 14.

Referring to FIG. 5, the sealing resin 18 is provided so as to fill the grooves 24 and cover the semiconductor elements 13. The sealing resin 18 can be provided by, for example, transfer molding. Alternatively, it is possible to employ a method of collectively sealing one block with resin.

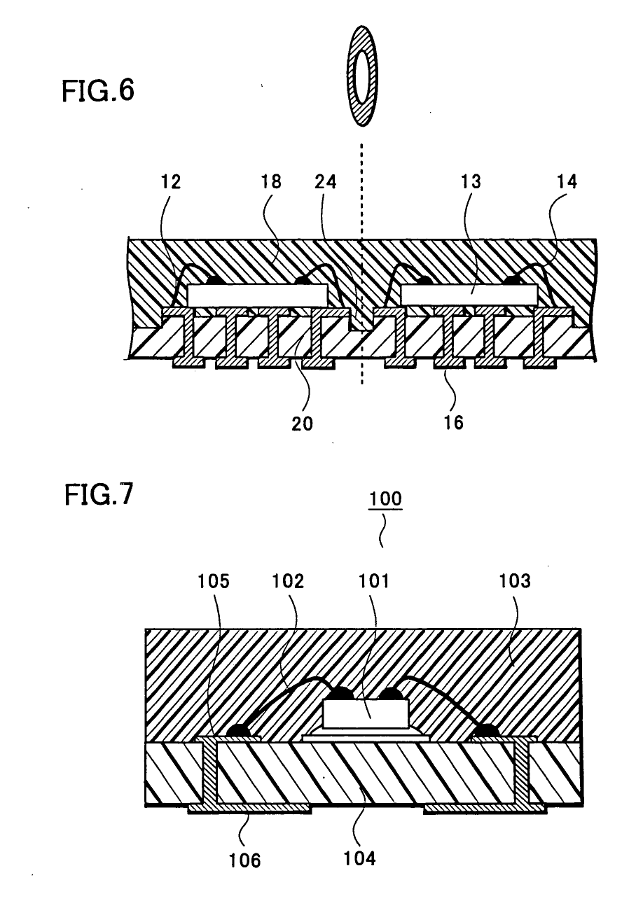

Referring to FIG. 6, dicing is performed at the borders of the units 21 to separate semiconductor devices. Herein, the grooves 24 are formed at the borders of the units 21, and the sealing resin 18 and the substrate 20 are diced near the center of each groove 24. With the aforementioned steps, the semiconductor device 10 as shown in FIG. 1 is manufactured.

According to the semiconductor device of the present embodiment, the step portion 15 and the sealing resin 18 firmly adhere to each other since the step portion 15 is provided in the periphery of the mounting substrate 11. Accordingly, it is possible to increase the adhesive strength between the sealing resin 18 and the mounting substrate 11. Furthermore, it is possible to prevent water and the like from filtrating into the interface therebetween. In addition, by providing the step portion 15, it is possible to prevent the plating lines 12B from being exposed to the outside from the interface of the mounting substrate 11 and the sealing resin 18. Accordingly, the reliability of the semiconductor device can be further increased.

According to the method of manufacturing the semiconductor device of the present embodiment, the plurality of units 21 each constituting a semiconductor device are formed in the substrate 20, and the conductive patterns of the units 21 are electrically connected to each other by the common plating lines 23 to plate the conductive patterns. Accordingly, it is possible to efficiently form the plated film by electroplating.

What is claimed is:

1. A semiconductor device, comprising:
a mounting substrate having a step portion in a periphery thereof;
a conductive pattern formed on a surface of the mounting substrate;
a semiconductor element fixed to the mounting substrate and electrically connected to the conductive pattern; and
sealing resin covering the surface of the mounting substrate and the step portion to seal the semiconductor element.

2. The semiconductor device according to claim 1, wherein the conductive pattern comprises a bonding pad electrically connected to the semiconductor element through a fine metallic wire and a plating line extending from the bonding pad to the step portion.

3. The semiconductor device according to claim 2, wherein a plurality of the bonding pads are arranged so as to surround the semiconductor element, further comprising a wiring portion extending from each of the plurality of bonding pads under the semiconductor element.

4. A method of manufacturing a semiconductor device, comprising:
forming first conductive patterns which constitute units and common plating lines on a front surface of a substrate, each of the units comprising bonding pads and plating lines extending from the respective bonding pads to a periphery, the common plating lines electrically connecting the plating lines of the units;
forming second conductive patterns on a back surface of the substrate, the second conductive patterns being electrically connected to the respective first conductive patterns;
forming a plated film to a surface of the first conductive patterns by electroplating using the common plating lines;
forming grooves on the front surface of the substrate by dicing the front surface of the substrate including the common plating lines to electrically separate the conductive patterns;
placing semiconductor elements on the front surface of the substrate;
providing sealing resin which fills the grooves and seals the semiconductor elements; and
separating the semiconductor elements by dicing the substrate and the sealing resin at borders of the units.

5. The method of manufacturing a semiconductor device according to claim 4, wherein the units are arranged in a matrix, and the common plating lines extend along the borders of the units into a grid.
